(19) United States
(12) Patent Application Publication
(10) Pub. No.: US 2025/0372365 A1
(43) Pub. Date: Dec. 4, 2025

(54) METHODS OF WIDENING THRESHOLD VOLTAGE TUNING RANGE FOR SEMICONDUCTOR DEVICES

(71) Applicant: Taiwan Semiconductor Manufacturing Company, Ltd., Hsin-Chu (TW)

(72) Inventors: Wei-Chin Lee, Taipei City (TW); Ji-Cheng Chen, Hsinchu City (TW); Yi-Lun Li, Hsinchu (TW); Hsuan-Yu Tung, Keelung (TW); Tsung-Han Shen, Hsinchu (TW); Chung-Yi Su, Taipei City (TW); Juan Peng Wong, Hsinchu City (TW); Hung-Chin Chung, Taoyuan County (TW); Da-Yuan Lee, Hsinchu County (TW); Weng Chang, Hsin-Chu (TW); Chi On Chui, Hsinchu City (TW)

(21) Appl. No.: 18/882,223

(22) Filed: Sep. 11, 2024

Related U.S. Application Data
(60) Provisional application No. 63/655,816, filed on Jun. 4, 2024.

(51) Int. Cl. H01L 21/02; H01L 21/8234; H01L 27/088; H01L 29/06; H01L 29/08; H01L 29/423; H01L 29/66; H01L 29/775; H01L 29/786

(52) U.S. Cl. CPC H01L 21/0228; H01L 21/02205; H10D 30/014; H10D 30/43; H10D 30/6735; H10D 30/6757; H10D 62/121; H10D 62/151; H10D 64/017; H10D 64/018; H10D 84/013; H10D 84/038; H10D 84/83

(57) ABSTRACT

Semiconductor devices and methods are provided. An exemplary method according to the present disclosure includes forming a dielectric layer over a portion of a substrate, forming a first p-type work function layer over the dielectric layer, wherein the first p-type work function layer comprises titanium nitride, forming a second p-type work function layer over the first p-type work function layer, wherein the second p-type work function layer comprises titanium nitride with dopants, forming an aluminum-containing N-type work function layer over second p-type work function layer, wherein the dopants in the second p-type work function layer reduces aluminum diffusion from aluminum-containing N-type work function layer into the second p-type work function layer, and forming a metal layer over the aluminum-containing N-type work function layer.

### PRIORITY

This application is a non-provisional application of and claims benefit of U.S. Provisional Patent Application Ser. No. 63/655,816, filed Jun. 4, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. Integrated circuits include a variety of circuit device components, such as transistors. One characteristic of a transistor is its threshold voltage. As transistor sizes become smaller, it is desirable to find ways to extend the threshold voltage tuning range without adversely affecting other aspects of the transistor.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 is a flowchart illustrating a method of forming a semiconductor structure, according to various embodiments of the present disclosure.

FIG. 2 illustrates a fragmentary top view of an exemplary structure to undergo various stages of operations in the method of FIG. 1, according to various aspects of the disclosure.

FIGS. 3, 4, 5, 6, 7, 8, 9, 10, 11, 12, 13, 14, 17, 18, 19, 20, 21A, 21B, and 22 illustrate fragmentary cross-sectional views of the structure during various fabrication stages in the method of FIG. 1, according to various aspects of the disclosure.

FIGS. 14A, 14B, 14C, 14D illustrate fragmentary cross-sectional views of various structures, according to various aspects of the disclosure.

FIG. 15 illustrates a simplified timing diagram of a cycle of an atomic layer deposition process, according to various aspects of the disclosure.

FIG. 16 illustrates a simplified timing diagram of a cycle of another atomic layer deposition process, according to various aspects of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed. For avoidance of doubts, the X, Y and Z directions in the figures are perpendicular to one another and are used consistently. Throughout the present disclosure, like reference numerals denote like features unless otherwise excepted.

A functional gate stack of a transistor includes a gate electrode over a gate dielectric layer. The gate electrode may include one or more work function layers with proper work functions such that the corresponding transistor is enhanced for its device performance (for example, reduced threshold voltage). As described above, it is desirable to find ways to extend the threshold voltage tuning range without adversely affecting other aspects of the transistor. One way to adjust the threshold voltage is to adjust the thickness of the work function layer that is part of the gate stack of the transistor. However, increasing the thickness of the work function metal layer becomes more difficult when producing smaller circuits.

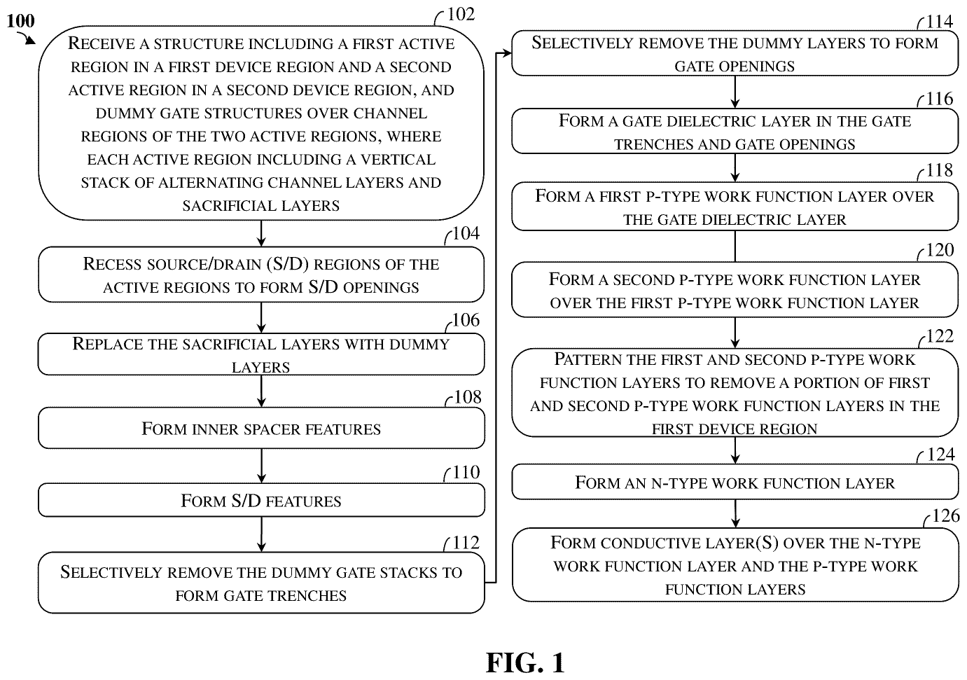

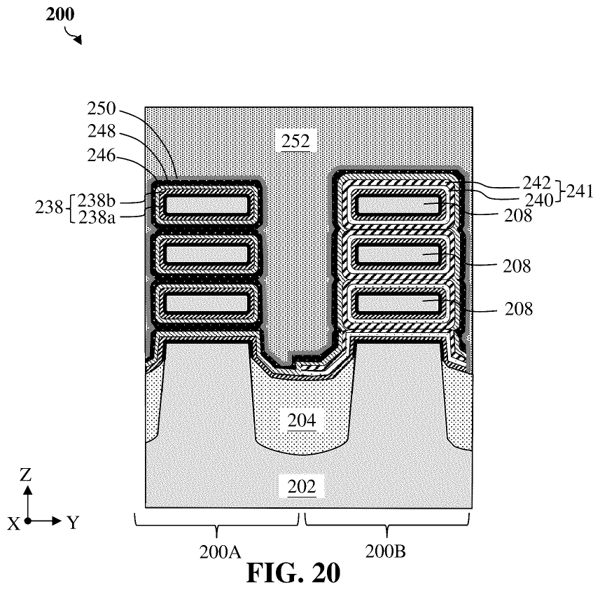

The present disclosure relates to methods of widening the threshold voltage tuning range of P-type transistors. A first mechanism of the present disclosure may introduce first type dopants to the work function layer of the P-type transistor to reduce aluminum diffusion, thereby increasing work function and reducing the threshold voltage of the P-type transistor; a second mechanism of the mechanism of the present disclosure may introduce second type dopants to the work function layer of the P-type transistor to reduce work function, thereby increasing the threshold voltage of the P-type transistor. Thus, the threshold voltage tuning range may be extended without adjusting the thickness of the work function layer. The two mechanisms will be described in more detail with reference to FIGS. 1-22.

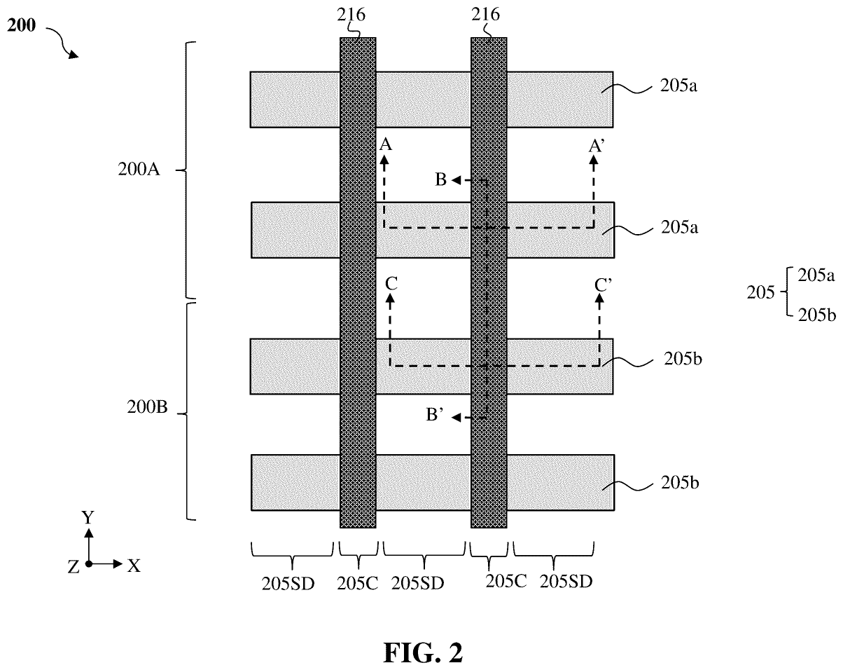

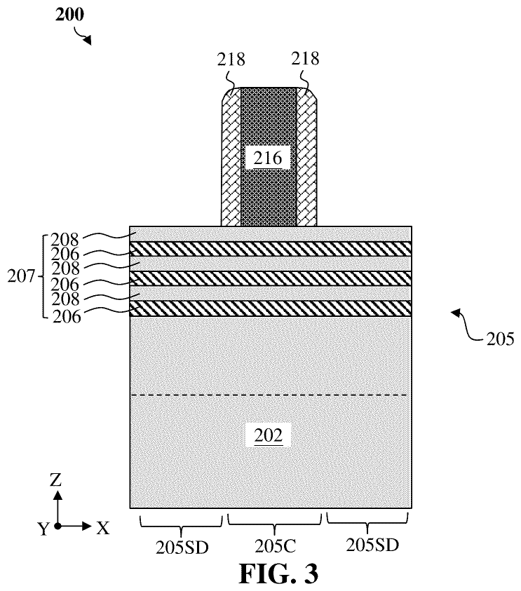

Referring to FIGS. 1 and 2-3, method 100 includes a block 102 where a structure 200 is received. FIG. 3 depicts a fragmentary cross-sectional view of the structure 200 taken along line A-A shown in FIG. 2. A fragmentary cross-sectional view of the structure 200 taken along line C-C shown in FIG. 2 is similar to FIG. 3 and is omitted for reason of simplicity. In this illustrated embodiment, the structure 200 includes a first device region 200A for forming N-type devices (e.g., N-type gate-all-around (GAA) transistors) and a second device region 200B for forming P-type devices (e.g., P-type GAA transistors). The structure 200 includes a substrate 202 (shown in FIG. 3). In an embodiment, the substrate 202 is a bulk silicon substrate (i.e., including bulk single-crystalline silicon). The substrate 202 may include other semiconductor materials in various embodiment, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof. In some alternative embodiments, the substrate 202 may be a semiconductor-on-insulator substrate, such as a silicon-on-insulator (SOI) substrate, a silicon germanium-on-insulator substrate, or a germanium-on-insulator substrate, and includes a carrier, an insulator on the carrier, and a semiconductor layer on the insulator. The substrate 202 can include various doped regions configured according to design requirements of semiconductor structure 200. P-type doped regions may include p-type dopants, such as boron, indium, other p-type dopant, or combinations thereof. N-type doped regions may include n-type dopants, such as phosphorus, arsenic, other n-type dopant, or combinations thereof. In some implementations, the substrate 202 includes doped regions formed with a combination of p-type dopants and n-type dopants. The various doped regions can be formed directly on and/or in substrate 202, for example, providing a p-well structure, an n-well structure, a dual-well structure, a raised structure, or combinations thereof. An ion implantation process, a diffusion process, and/or other suitable doping process can be performed to form the various doped regions.

The structure 200 also includes multiple fin-shaped active regions (e.g., fin-shaped active regions 205a, 205b) disposed over the substrate 202. In the present embodiments, each of the fin-shaped active regions 205a is formed in the first device region 200A (shown in FIG. 2) of the structure 200, and each of the fin-shaped active regions 205b is formed in the second device region 200B of the structure 200. The fin-shaped active regions 205a, 205b may be separately or collectively referred to as a fin-shaped active region 205 or fin-shaped active regions 205. Each of the fin-shaped active regions 205 extends lengthwise along the X direction and is divided into channel regions 205C and source/drain regions 205SD. Source/drain region(s) may refer to a source region or a drain region, individually or collectively dependent upon the context.

The fin-shaped active region 205 may be formed from a top portion of the substrate 202 and a vertical stack 207 (shown in FIG. 3) of alternating semiconductor layers 206 and 208 using a combination of lithography and etch steps. In the depicted embodiment, the vertical stack 207 of alternating semiconductor layers 206 and 208 includes a number of channel layers 208 interleaved by a number of sacrificial layers 206. Each channel layer 208 may include a semiconductor material such as, silicon, germanium, silicon carbide, silicon germanium, GeSn, SiGeSn, SiGeCSn, other suitable semiconductor materials, or combinations thereof, while each sacrificial layer 206 has a composition different from that of the channel layer 208. In an embodiment, the channel layer 208 includes silicon (Si), the sacrificial layer 206 includes silicon germanium (SiGe). The channel layers 208 and the sacrificial layers 206 may be epitaxially deposited on the substrate 202 using molecular beam epitaxy (MBE), vapor-phase epitaxy (VPE), ultra-high vacuum CVD (UHV-CVD), and/or other suitable epitaxial growth processes. In some examples, each of the fin-shaped active regions 205 may include a total of three to ten pairs of alternating sacrificial layers 206 and channel layers 208; of course, other configurations may also be applicable depending upon specific design requirements.

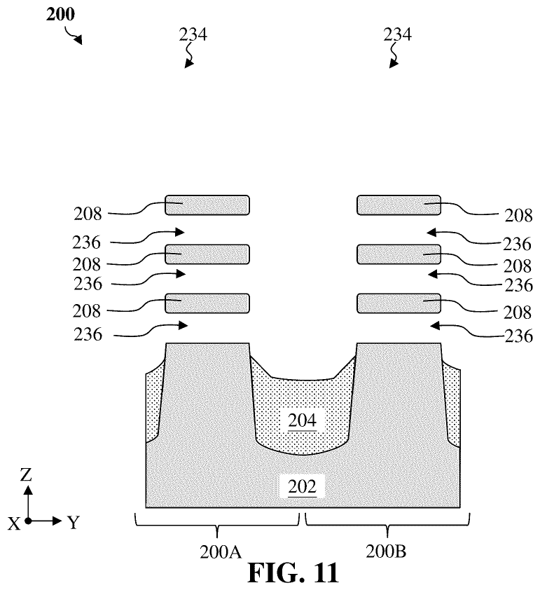

The structure 200 also includes an isolation feature 204 (shown in FIG. 11) formed over the substrate 202 to isolate two adjacent fin-shaped active regions. The isolation feature 204 may also be referred to as a shallow trench isolation (STI) feature. In some embodiments, the STI feature 204 may include silicon oxide, silicon oxynitride, fluorine-doped silicate glass (FSG), a low-k dielectric, combinations thereof, and/or other suitable materials. In some embodiments, a top surface of the STI feature 204 is lower than a top surface of the top portion of the substrate. The top surface of the STI feature 204 may be a curved (e.g., concave) surface having a lowest point near its middle.

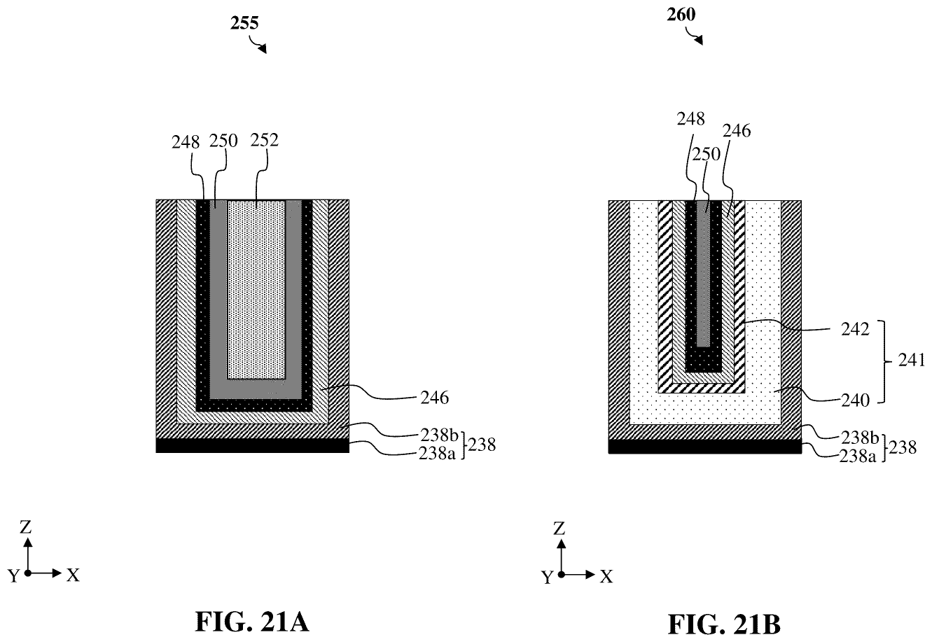

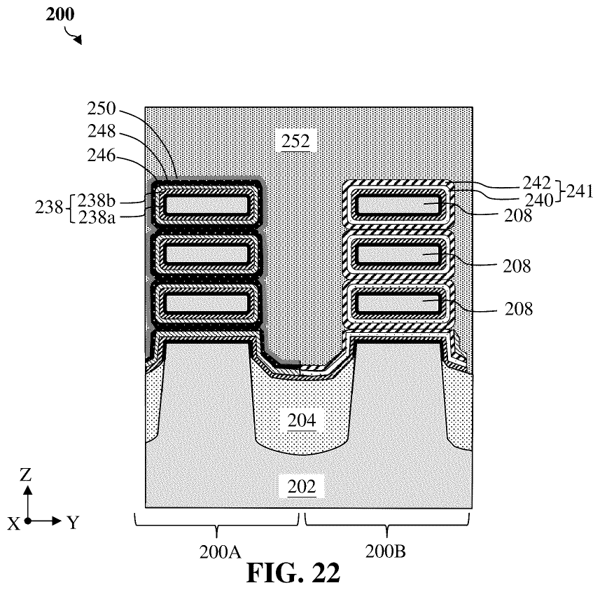

Still referring to FIGS. 2-3, the structure 200 also includes dummy gate structures 216 formed over channel regions 205C of the fin-shaped active regions 205. The channel regions 205C and the dummy gate structures 216 also define source/drain regions 205SD that are not vertically overlapped by the dummy gate structures 216. Each of the channel regions 205C is disposed between two source/drain regions 205SD along the X direction. Two dummy gate structures 216 are shown in FIG. 2 but the structure 200 may include other numbers of dummy gate structures. In this embodiment, a gate replacement process (or gate-last process) is adopted where the dummy gate structures 216 serve as placeholders for functional gate stacks (e.g., functional gate stacks 255, 260 shown in FIGS. 21A and 21B). Other processes for forming the functional gate stacks are possible. In the present embodiments, although not separately shown, each of the dummy gate structures 216 includes a dummy gate dielectric layer (e.g., silicon oxide) and a dummy gate electrode (e.g., polysilicon) disposed over the dummy gate dielectric layer. The structure 200 also includes gate spacers 218 extending along sidewalls of the dummy gate structures 216. In some embodiments, the gate spacers 218 may include silicon oxide, silicon oxycarbide, silicon carbonitride, silicon oxycarbonitride, silicon nitride, zirconium oxide, aluminum oxide, or a suitable dielectric material. The gate spacer 218 may be a single-layer structure or a multi-layer structure.

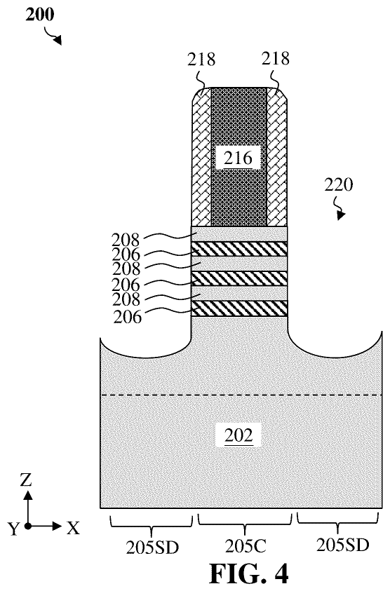

Referring to FIGS. 1 and 4, method 100 includes a block 104 where source/drain regions 205SD of the fin-shaped active regions 205 are recessed to form source/drain openings 220. In some embodiments, the source/drain regions 205SD of the fin-shaped active region 205 that are not covered by the dummy gate structures 216 and the gate spacers 218 are anisotropically etched by a dry etch or a suitable etching process to form source/drain openings 220. An exemplary dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. The source/drain openings 220 extend through the stack 207 of channel layers 208 and sacrificial layers 206 and extend into the substrate 202. As illustrated by FIG. 4, sidewalls of the channel layers 208 and the sacrificial layers 206 are exposed in the source/drain openings 220.

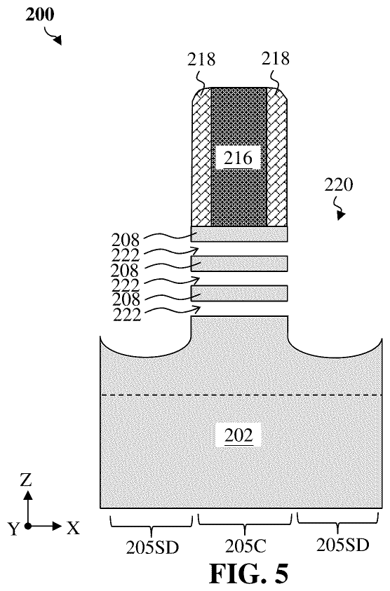

Referring to FIGS. 1 and 5-6, method 100 includes a block 106 where the sacrificial layers 206 are replaced with dummy layers 224. With reference to FIG. 5, after the formation of the source/drain openings 220, the sacrificial layers 206 interleaving the channel layers 208 in the channel region 205C are selectively removed. The selective removal of the sacrificial layers 206 releases the channel layers 208 to form channel members 208. Depending on the design, the channel members 208 may take form of nanowires, nanosheets, or other nanostructures. The selective removal of the sacrificial layers 206 forms spaces 222 between and around adjacent channel members 208. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

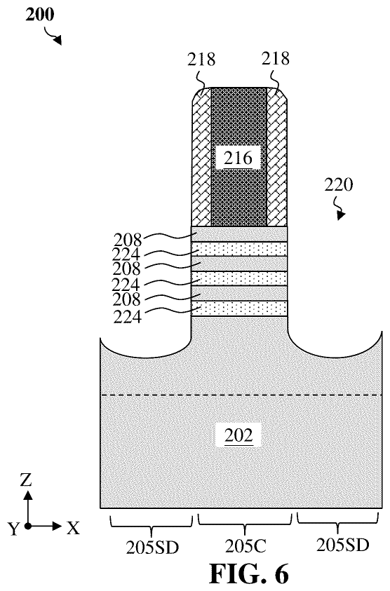

With reference to FIG. 6, after the selective removal of the sacrificial layers 206, in an example process, a dielectric material layer is deposited around the channel members 208 and over the source/drain openings 220. The dielectric material layer fills the space 222 among the channel members 208 and covers end sidewalls of the channel members 208. After the deposition of the dielectric material layer, an etching process is performed to selectively etch the dielectric material layer, thereby forming the dummy layers 224 interleaved by the channel members 208. The dielectric material layer may include silicon oxide, silicon nitride, silicon oxynitride, silicon carbonitride, silicon oxycarbonitride, high-K dielectric materials (e.g., aluminum oxide, hafnium oxide), other suitable materials, or combinations thereof, and may be deposited using plasma enhanced chemical vapor deposition (PECVD) or atomic layer deposition (ALD) or other suitable methods. In an embodiment, the dielectric material layer includes silicon oxide.

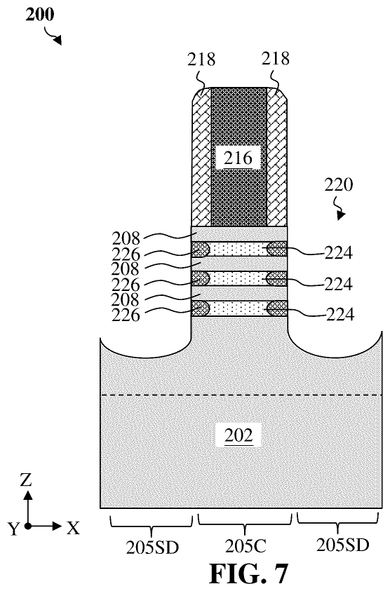

Referring to FIGS. 1 and 7, method 100 includes a block 108 where inner spacer features 226 are formed. After forming the dummy layers 224, an etching process is performed to selectively recess the dummy layers 224 to form inner spacer recesses (now filled by inner spacer features 226). The etching process selectively and partially recesses the dummy layers 224 to form inner spacer recesses, while the exposed channel members 208 are not significantly etched. In an embodiment where the channel members 208 consist essentially of silicon (Si) and the dummy layers 224 are formed of silicon oxide, the selective recess of the dummy layer 224 may be performed using a selective wet etch process or a selective dry etch process. The extent at which the dummy layers 224 are recessed is controlled by duration of the etching process. In an alternative embodiment, the etch back of the dielectric material layer and the selective and partial recess of the dummy layers 224 are conducted by performing a same etching process. Inner spacer features 226 are then formed in the inner spacer recesses. In an example process, after the formation of the inner spacer recesses, an inner spacer material layer (not shown) is deposited over the structure 200, including in the inner spacer recesses. The deposited inner spacer material layer is then etched back to remove excessive inner spacer material layer, thereby forming the inner spacer features 226. The etch back process at block 108 may be a dry etching process that is similar to the dry etching process used in the formation of the source/drain openings 220. The inner spacer features 226 track the shapes of the corresponding inner spacer recesses. The inner spacer material layer may include silicon oxide, silicon nitride, silicon oxycarbide, silicon oxycarbonitride, silicon carbonitride, metal nitride, or a suitable dielectric material.

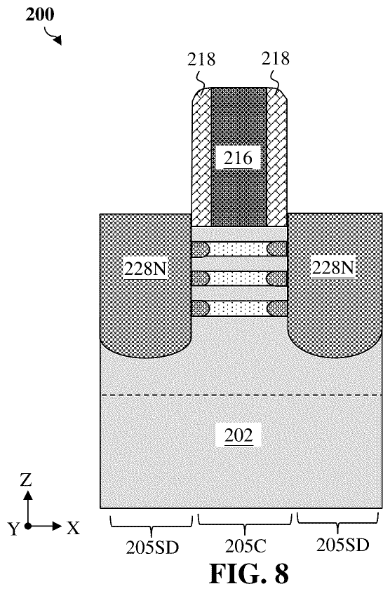

Referring to FIGS. 1 and 8, method 100 includes a block 110 where source/drain features are formed adjacent to the channel regions 205C. The source/drain features are formed in and/or over source/drain regions 205SD and coupled to the channel layers 208 in the channel regions 205C. In the present embodiments, N-type source/drain features 220N are formed in the first device region 200A, and P-type source/drain features (not shown) are formed in the second device region 200B. Exemplary N-type source/drain features may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Exemplary p-type source/drain features may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process.

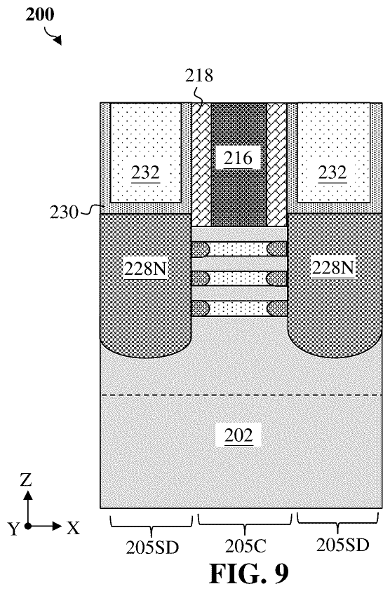

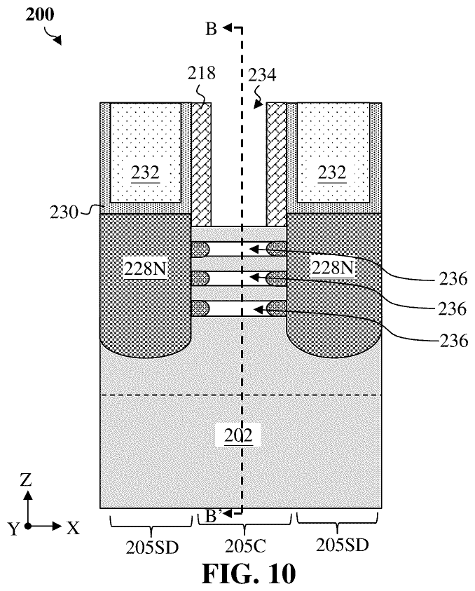

Referring to FIGS. 1 and 9-10, method 100 includes a block 112 where the dummy gate structures 216 are selectively removed to form gate trenches 234. With reference to FIG. 9, after forming the source/drain features, a contact etch stop layer (CESL) 230 and an interlayer dielectric (ILD) layer 232 are formed over the structure 200. The CESL 230 is configured to protect the various underlying components during subsequent fabrication processes and may include silicon nitride, silicon oxynitride, and/or other suitable materials and may be formed by atomic layer deposition (ALD), chemical vapor deposition (CVD), plasma-enhanced chemical vapor deposition (PECVD) process and/or other suitable deposition or oxidation processes. As shown in FIG. 9, the CESL 230 may be formed on top surfaces of the source/drain features (e.g., the N-type source/drain features 228N) and sidewalls of the gate spacers 218. The ILD layer 232 is deposited by a CVD process, a PECVD process or other suitable deposition technique over the structure 200 after the depositing of the CESL 230. The ILD layer 232 may include silicon oxide, a low-k dielectric material, tetraethyl orthosilicate (TEOS), doped silicon oxide (e.g., BPSG, FSG, PSG, BSG, etc.), other suitable dielectric materials, or combinations thereof. One or more chemical mechanical planarization (CMP) processes may be performed to planarize the top surface of the structure 200 to expose dummy gate electrode of the dummy gate structures 216. With reference to FIG. 10, the dummy gate structures 216 are selectively removed to form gate trenches 234 over the channel regions 205C. The dummy gate structures 216 are selectively removed by an etching process. The etching process for removing the dummy gate structures 216 may include any suitable process, such as a dry etching process, a wet etching process, or combinations thereof, and is configured to selectively remove the dummy gate structures 216.

Referring to FIGS. 1 and 10-11, method 100 includes a block 114 where the dummy layers 224 are selectively removed to form gate openings 236. FIG. 11 depicts a cross-sectional view of the structure 200 taken along line B-B′ shown in FIG. 2 and FIG. 10. After the removal of the dummy gate structures 216, the dummy layers 224 are selectively removed to form gate openings 236. The selective removal of the dummy layers 224 may be implemented by a selective dry etch, a selective wet etch, or other selective etching process. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. In some embodiments, the selective wet etching includes an APM etch (e.g., ammonia hydroxide-hydrogen peroxide-water mixture).

Referring to FIGS. 1 and 12, method 100 includes a block 116 where a gate dielectric layer 238 is formed over the structure 200. In some embodiments, the gate dielectric layer 238 is a multi-layer structure that includes an interfacial layer 238a and a high-K dielectric layer 238b over the interfacial layer 238a. In some other implementations, the interfacial layer 238a may be formed by thermal oxidization and may include silicon oxide. That is, the interfacial layer 238a is only formed along exposed surfaces of the semiconductor features (e.g., the top portion of the substrate 202 and the channel members 208). In some embodiments, the interfacial layer 238a may be conformally deposited over the substrate 202, including in the gate trenches 234 and the gate openings 236 and on the STI feature 204. The high-K dielectric layer 238b is then conformally deposited over the structure 200 by performing a deposition process (e.g., CVD, ALD) to have a generally uniform thickness over the top surface of the structure 200 to partially fill the gate trenches 234 and the gate openings 236. The term “conformally” may be used herein for ease of description of a layer having substantially uniform thickness over various regions. The high-K dielectric layer 238b may include dielectric materials having a high dielectric constant, for example, greater than a dielectric constant of silicon oxide. Exemplary high-K dielectric materials include hafnium, zirconium, tantalum, titanium, oxygen, nitrogen, other suitable constituent, or combinations thereof. In some implementations, the high-K dielectric layer 238b may include a high-k dielectric material including, for example, HfO₂, HfSiO, HfSiON, HfTaO, HfTiO, HfZrO, ZrO₂, TiO₂, Ta₂O₅, other suitable high-K dielectric material, or combinations thereof.

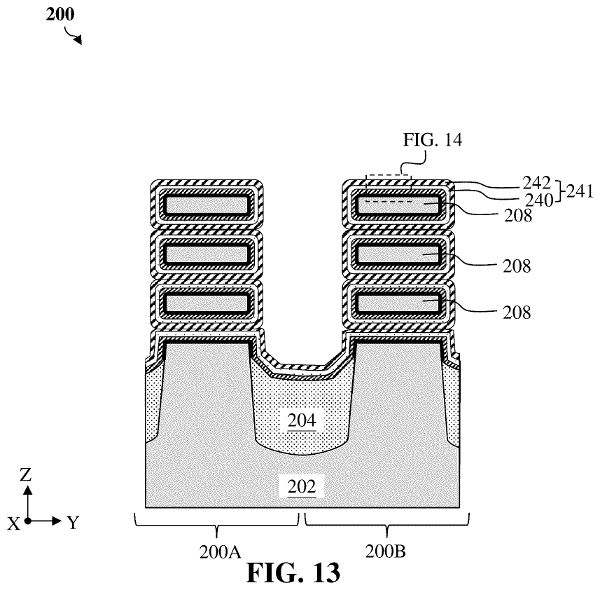

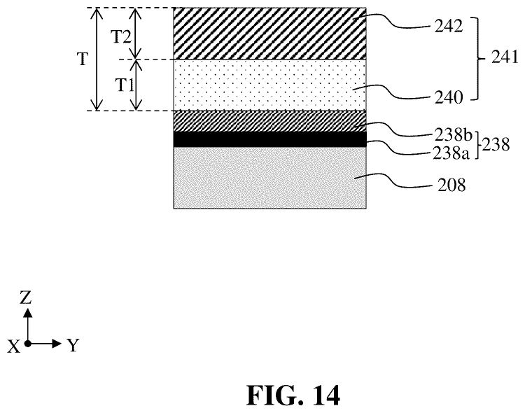

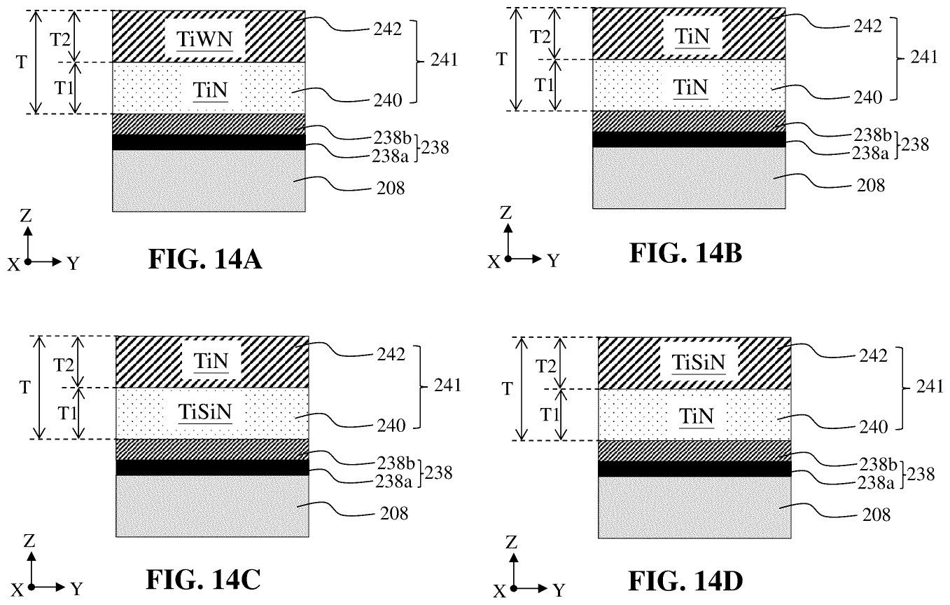

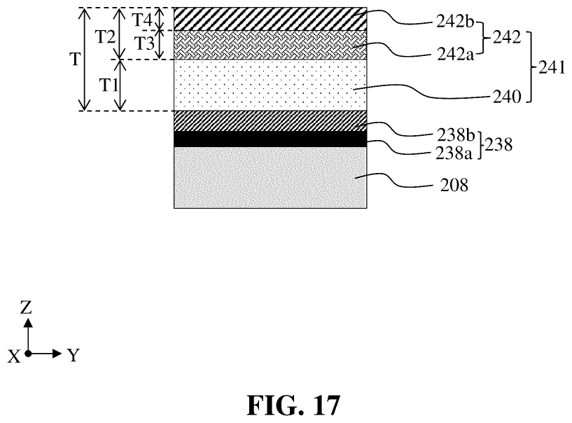

In this illustrated embodiments, to effectively adjusting the work function of the gate stack of the P-type transistor without significantly affecting other physical or electrical properties (e.g., gate resistance Rg, channel resistance Rch) of the gate stack, instead of forming a single P-type work function layer having a thickness T (shown in FIG. 14), the gate stack of the P-type transistor includes a multi-layer P-type work function structure 241 having the thickness T. For example, in one embodiment, the multi-layer P-type work function structure 241 has a first P-type work function layer 240 and a second P-type work function layer 242 over the first P-type work function layer 240. The second P-type work function layer 242 may be a single-layer work function layer (described with reference to FIG. 14) or may include two sub layers (described with refence to FIG. 17).

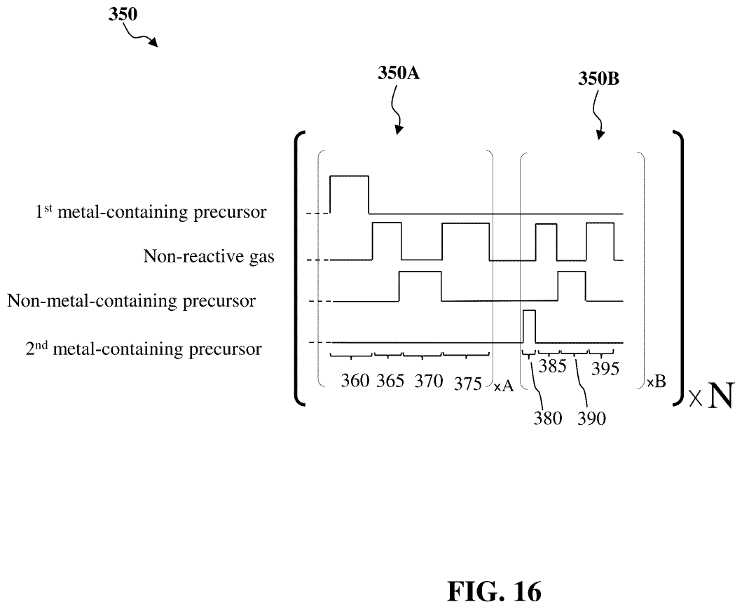

In the present embodiments, two different mechanisms may be implemented to widen the threshold voltage tuning range of a P-type transistor without changing a total thickness T of its P-type work function structure 241. A first mechanism of the two mechanisms includes introducing first type dopants to the first P-type work function layer 240 and/or the second P-type work function layer 242. The first type dopants may reduce or prevent aluminum from being diffused from an aluminum-containing N-type work function layer over the second P-type work function layer 242 into the first and/or the second P-type work function layers 240 and 242. A reduced extent of aluminum diffusivity may lead to an increased work function for gate stack of the P-type transistor and thus achieve a decreased threshold voltage for the P-type transistor. The first type dopants may include tungsten, oxygen, fluorine, or other suitable compositions. The first type dopants may be introduced by atomic layer deposition process, plasma doping, control of parameters during the deposition of the first and/or the second P-type work function layers 240 and 242, or other suitable processes. An example for forming the first-type dopants-containing P-type work function layer will be described below in detail with reference to FIG. 16.

A second mechanism of the two mechanisms includes introducing second type dopants to the first P-type work function layers 240. Intrinsic work function positions of the second type dopants may be less than the intrinsic work function position of material of the first P-type work function layer 240. Thus, introducing the second type dopants to the first P-type work function layer 240 may reduce the work function position for the first P-type work function layer 240, resulting an increased threshold voltage for the P-type transistor. The second type dopants may include silicon, aluminum, tantalum, or other suitable compositions. An example for forming the second-type dopants-containing P-type work function layer will be described below in detail with reference to FIG. 16.

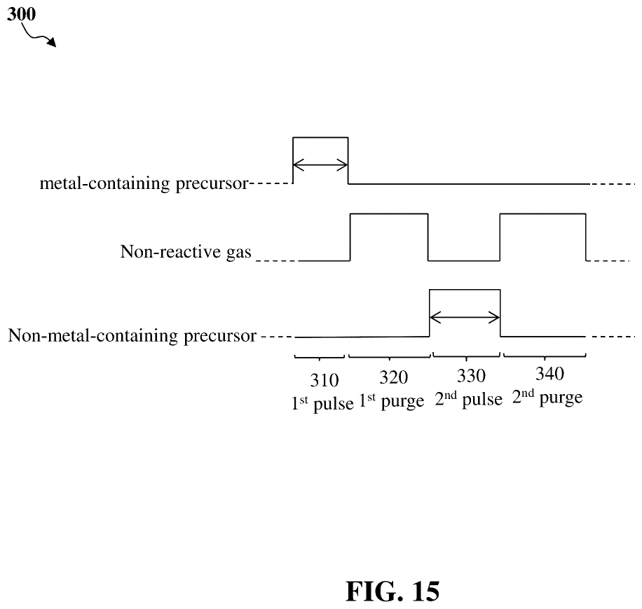

Referring to FIGS. 1 and 13-15, method 100 includes a block 118 where a first P-type work function layer 240 is deposited over the structure 200. FIG. 14 depicts an enlarged portion of the structure 200. FIG. 15 depicts a simplified diagram showing an example cycle of an atomic layer deposition (ALD) process 300 for forming the first work function layer 240 of the P-type work function structure 241.

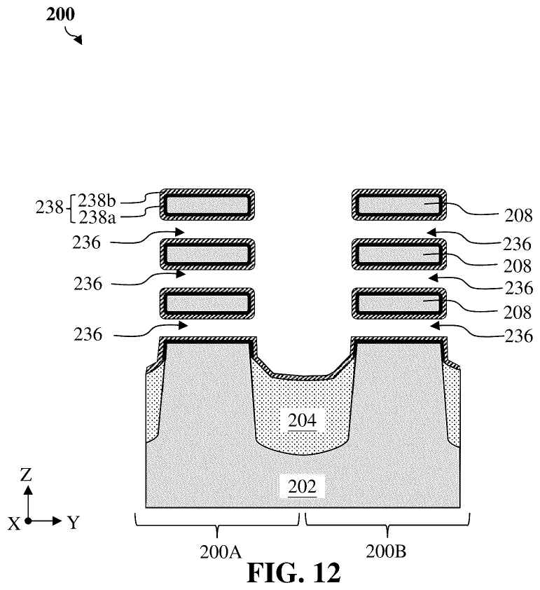

With reference to FIGS. 13, 14, and 15, the first P-type work function layer 240 is conformally deposited over the substrate 202, including on the high-K dielectric layer 238b that is over the channel layers 208. The first P-type work function layer 240 may be deposited using ALD, CVD, PVD, or other suitable processes. The first P-type work function layer 240 includes a P-type work function materials for P-type transistors, such as TiN, TaN, TiSiN, TaSiN, Ru, Mo, Al, WN, WCN, ZrSi₂, MoSi₂, TaSi₂, NiSi₂, other P-type work function materials, or combinations thereof. In some embodiments, the first P-type work function layer 240 completely fills a remaining portion of the gate openings 236 between the adjacent channel layers 208. In this illustrated embodiment, the first P-type work function layer 240 does not completely fill a remaining portion of the gate openings 236 between the adjacent channel layers 208. In some embodiments, the first P-type work function layer 240 has a thickness T1 of about 6 Å to about 18 Å.

An ALD process 300 represented by FIG. 15 may be implemented to form the first P-type work function layer 240. At an initial process, the structure 200 represented by FIG. 12 is loaded into a process chamber, where the process chamber is prepared for the ALD process 300 to form a work function layer, such as the first P-type work function layer 240, over the gate dielectric layer 238 and the substrate 202. After being loaded into the process chamber, the structure 200 is exposed to a metal-containing precursor (which can be referred to as a pulse process 310 or a metal-containing pulse process 310). A purge process 320 is then performed to remove any remaining metal-containing precursor and any byproducts from the process chamber. Then, the structure 200 is exposed to a non-metal-containing precursor (which can be referred to as a non-metal-containing pulse process 330 or a pulse process 330). A purge process 340 is then performed to remove any remaining non-metal-containing precursor and any byproducts from the process chamber. The pulse process 310, purge process 320, pulse process 330, purge process 340 constitute one ALD cycle, which includes two deposition phases (processes 310 and 330) and two purge phases (processes 320 and 340). Each ALD cycle is a self-limiting process, where less than or equal to about one monolayer is deposited during each ALD cycle. The ALD cycle is repeated until the first P-type work function layer 240 reaches a desired (target) thickness T1. In embodiments where the first P-type work function layer 240 incudes titanium nitride, the metal-containing precursor may include titanium tetrachloride (TiCl₄), tetrakis(dimethylamido)titanium (TDMAT), tetrakis(diethylamido)titanium (TDEAT), or other suitable materials, and the non-metal-containing precursor may include NH₃, nitrogen, N₂H₄, or other suitable materials. In an embodiment, the metal-containing precursor includes TiCl₄, and the non-metal-containing precursor includes NH₃. A carrier gas may be used to deliver the precursors to the process chamber. In some embodiments, the carrier gas may be an inert gas, such as an argon-containing gas, a helium-containing gas, other suitable inert gas, or combinations thereof. In some embodiments, each of the first purge process 320 and the second purge process 340 implements an inert gas, such as an argon-containing gas, a helium-containing gas, other suitable inert gas, or combinations thereof.

Referring now to FIGS. 1, 13, 14, and 16, method 100 includes a block 120 where a second P-type work function layer 242 is deposited over the first P-type work function layer 240. FIG. 14 depicts the enlarged portion of the structure 200. FIG. 16 depicts a simplified diagram showing an example cycle of an atomic layer deposition (ALD) process 350 for forming the second P-type work function layer 242 of the P-type work function structure 241. After forming the first P-type work function layer 240, the second P-type work function layer 242 is conformally deposited over the substrate 202, including on the first P-type work function layer 240. The second P-type work function layer 242 may be deposited using ALD, CVD, PVD, or other suitable processes. In this illustrated embodiment, the second P-type work function layer 242 completely fills a remaining portion of the gate openings 236 between the adjacent channel layers 208. In some other embodiments, the second P-type work function layer 242 does not completely fill a remaining portion of the gate openings 236 between the adjacent channel layers 208. The second P-type work function layer 242 includes a P-type work function metal for P-type transistors, such as dopants-containing TiN (e.g., TiWN, TiSiN), other P-type work function materials (e.g., dopants-containing TaN or other dopants-containing P-type work function materials), or combinations thereof. In some embodiments, the second P-type work function layer 242 has a thickness T2 of about 7 Å to about 19 Å.

According to the first mechanism described above, first type dopants (e.g., tungsten, oxygen, fluorine) may be introduced into the first P-type work function layer 240 and/or the second P-type work function layer 242 to reduce or prevent aluminum from being diffused from the aluminum-containing N-type work function layer into the first and/or the second P-type work function layers 240 and 242 to achieve a decreased threshold voltage for the P-type transistor. In an example illustrated by FIG. 14A, tungsten (W) is introduced to the second P-type work function layer 242. For example, the second P-type work function layer 242 includes tungsten-doped titanium nitride (titanium tungsten nitride (TiWN)).

An ALD process 350 represented by FIG. 16 is implemented for forming the TiWN-based second P-type work function layer 242. The ALD process 350 includes a first half cycle 350A for forming monolayer(s) of tungsten nitride (WN) followed by a second half cycle 350B for forming monolayer(s) of titanium nitride (TiN). That is, upon completion of the ALD process 350, the second P-type work function layer 242 includes a laminated structure comprising alternating monolayer(s) of WN and monolayer(s) of TiN. The interdiffusion of elements of the monolayers forms the second P-type work function layer 242 including tungsten-doped titanium nitride (titanium tungsten nitride (TiWN)).

At an initial process, after forming the first P-type work function layer 240, the structure 200 is loaded into a process chamber, where the process chamber is prepared for the ALD process 350 to form the second P-type work function layer 242 over the first P-type work function layer 240 and the substrate 202.

After being loaded into the process chamber, the structure 200 is exposed to a first metal-containing precursor (which can be referred to as a pulse process 360 or a metal-containing pulse process 360). A purge process 365 is then performed to remove any remaining first metal-containing precursor and any byproducts from the process chamber. Then, the structure 200 is exposed to a first non-metal-containing precursor (which can be referred to as a non-metal-containing pulse process 370 or a pulse process 370). A purge process 375 is then performed to remove any remaining first non-metal-containing precursor and any byproducts from the process chamber. The pulse process 360, purge process 365, pulse process 370, purge process 375 constitute the first half cycle 350A of an ALD cycle of the ALD process 350. Each first half cycle 350A of the ALD cycle is a self-limiting process, where less than or equal to about one monolayer is deposited during each first half cycle 350A. The first half cycle 350A is repeated until the monolayers of tungsten nitride (WN) reaches a desired (target) thickness. For example, within a cycle of the ALD process 350, the first half cycle 350A may be performed for a number A of times before proceeding to the second half cycle 350B, where A is a positive integer. That is, a cycle of the ALD process 350 may include performing the first half cycle 350A multiple times.

After performing the first half cycle 350A, the cycle of the ALD process 350 proceeds to the second half cycle 350B. The structure 200 having the monolayers of tungsten nitride (WN) is exposed to a second metal-containing precursor (which can be referred to as a second metal-containing pulse process 380 or a pulse process 380). A purge process 385 is then performed to remove any remaining second metal-containing precursor and any byproducts from the process chamber. Then, the structure 200 is exposed to a second non-metal-containing precursor (which can be referred to as a second non-metal-containing pulse process 390 or a pulse process 390). A purge process 395 is then performed to remove any remaining second non-metal-containing precursor and any byproducts from the process chamber. The second metal-containing pulse process 380, purge process 385, second non-metal-containing pulse process 390, and purge process 395 constitute the second half cycle 350B of an ALD cycle of the ALD process 350. Each second half cycle 350B of the ALD cycle is a self-limiting process, where less than or equal to about one monolayer is deposited during each second half cycle 350B. The second half cycle 350B is repeated until the monolayers of titanium nitride (TiN) reaches a desired (target) thickness. For example, the second half cycle 350B may be performed for a number B of times before moving to a next cycle of the ALD process 350, where B is a positive integer. The entire cycle (including the first half cycle 350A and the second half cycle 350B) of the ALD process 350 may be repeated multiple times until the second P-type work function layer 242 reaches the desired (target) thickness T2. In some embodiments, a carrier gas is used to deliver the precursors to the process chamber. In some embodiments, the carrier gas is an inert gas, such as an argon-containing gas, a helium-containing gas, other suitable inert gas, or combinations thereof. In some embodiments, each of the purge processes 365, 375, 385, 395 implements an inert gas, such as an argon-containing gas, a helium-containing gas, other suitable inert gas, or combinations thereof.

In embodiments where the second P-type work function layer 242 incudes titanium tungsten nitride, the first metal-containing precursor may include tungsten hexafluoride (WF₆), tungsten pentachloride (WCl₅), tungsten hexachloride (WCl₆), tungsten carbonyls (e.g., W(CO)₆), tris(3-hexyne) tungsten carbonyl (W(CO)(CH₃CH₂C≡CCH₂CH₃)₃), Bis(tert-butylimino)bis(dimethyl amino)tungsten(VI) (((CH₃)₃CN)₂W(N(CH₃)₂)₂), or other suitable tungsten-containing precursors. The second metal-containing precursor may include titanium tetrachloride (TiCl₄), tetrakis(dimethylamido)titanium (TDMAT), tetrakis(diethylamido)titanium (TDEAT), or other suitable titanium-containing precursors. The non-metal-containing precursor may include NH₃, nitrogen, N₂H₄, or other suitable materials. In this present embodiment, both the first half cycle 350A and the second half cycle 350B use a same non-metal-containing precursor, while in some other embodiments, the first half cycle 350A and the second half cycle 350B may implement different non-metal-containing precursors. In an embodiment, an atomic percentage of tungsten in the TiWN-based second P-type work function layer 242 is in a range between about 5% and about 27%. If the atomic percentage of tungsten in the TiWN-based second P-type work function layer 242 is less than 5%, the work function of the gate stack 260 and thus the resulted threshold voltage may not be effectively tuned; and if the atomic percentage of tungsten TiWN-based second P-type work function layer 242 is greater than 27%, the adhesion between the second P-type work function layer 242 and photoresist that will be formed on the TiWN-based second P-type work function layer 242 in subsequent patterning process may not be good enough, leading to unsatisfactory patterning result. In an embodiment, to obtain the satisfactory tungsten concentration, a ratio of the number B to the number A is in a range between about 3 and 10. That is, a cycle of the ALD process 350 may include performing the first half cycle 350A for one time and performing the second half cycle 350B for 3 to 10 times. In this illustrated embodiment, the first half cycle 350A is performed prior to the performing of the second half cycle 350B. In some alternative embodiments, the second half cycle 350B is performed prior to the performing of the first half cycle 350A. Additional steps can be provided before, during, and after ALD process 350, and some of the steps described can be moved, replaced, or eliminated for additional embodiments of ALD process 350.

Various parameters of the ALD process 350 can be tuned to achieve desired growth characteristics, such as a flow rate of a deposition gas (including the titanium-containing precursor gas, the tungsten-containing precursor gas, the nitrogen-containing precursor gas, and/or a carrier gas), a concentration (or dosage) of the titanium-containing precursor gas, a concentration (or dosage) of the tungsten-containing precursor gas, a concentration (or dosage) of the nitrogen-containing precursor gas, a concentration (or dosage) of the carrier gas, a ratio of the concentration of the titanium-containing precursor gas to a ratio of the concentration of the tungsten-containing precursor gas, a ratio of the concentration of the metal-containing precursor gas to the concentration of the non-metal-containing precursor gas, a power of a radiofrequency (RF) source (for example, used during the deposition process to generate a plasma), a bias voltage (for example, applied during the deposition process to excite the plasma), a pressure of the process chamber, a duration of the deposition process, other suitable deposition parameters, or combinations thereof. In some embodiments, a ratio of a duration of the second pulse process 370 to a duration of the first pulse process 360 is less than 2.5. In an embodiment, a duration of the first pulse process 360 in the first half cycle 350A is between about 0.5 second to 10 seconds. In some embodiments, a temperature maintained in the process chamber during the second metal-containing pulse process 380 is about 300° C. to about 400° C. In some implementations, each cycle of the ALD 350 has the same ratio of the number B to the number A, and the concentration of tungsten in second P-type work function layer 242 is uniform across the second P-type work function layer 242. In some other implementations, one or more cycles of the ALD process 350 have different ratios of the number B to the number A, and the concentration of tungsten in second P-type work function layer 242 is non-uniform across the second P-type work function layer 242. For example, with reference to FIG. 14A, the concentration of tungsten in second P-type work function layer 242 may have a graded profile that gradually decreases from bottom to top or a stepwise profile that decreases from bottom to top. As described above, the concentration of tungsten in second P-type work function layer 242 is in a range between about 5% to about 27%. In an embodiment, a bottom surface of the second P-type work function layer 242 has a tungsten concentration of about 27%, and a top surface of the second P-type work function layer 242 has a tungsten concentration of about 5%.

In the above embodiments, tungsten is introduced as dopants to the titanium nitride containing P-type work function structure 241. In another embodiment represented by FIG. 14B, oxygen may be introduced as dopants to the titanium nitride containing P-type work function structure 241. The oxygen-containing dopants may be introduced by performing an oxygen plasma doping to the first P-type work function layer 240 and/or the second P-type work function layer 242. For example, upon introducing oxygen as dopants, both the first P-type work function layer 240 and the second P-type work function layer 242 may include oxygen-containing titanium nitride. In some other implementations, a baking process may be applied to titanium nitride-based first P-type work function layer 240 and/or the second P-type work function layer 242 to increase its corresponding oxygen concentration. In some other implementations, the first P-type work function layer 240 includes titanium nitride formed by the ALD process 300, and a temperature maintained in a corresponding process chamber during the first pulse process 310 is about 300° C. to about 400° C.; the second P-type work function layer 242 includes titanium nitride formed by the ALD process 300, and a temperature maintained in a corresponding process chamber during the first pulse process 310 is about 300° C. to about 400° C. For embodiments in which the first P-type work function layer 240 and second P-type work function layer 242 that include titanium nitride formed by the ALD process 300, and the temperature maintained in a corresponding process chamber during the first pulse process 310 is about 300° C. to about 400° C., an oxygen concentration of the titanium nitride-based first P-type work function layer 240 and second P-type work function layer 242 is in a range between about 15% and about 50%. If the temperature is less than about 300° C., oxygen concentration of the first P-type work function layer 240 and the second P-type work function layer 242 may be too high, leading to an increased gate resistance Rg; and if the temperature is greater than about 400° C., the titanium-containing precursor (TiCl₄) may be fully consumed and as a result, an oxygen concentration of the first P-type work function layer 240 and the second P-type work function layer 242 may be too low to affect the work function of the titanium nitride. In an embodiment, the temperature associated with the ALD process 300 for forming the second P-type work function layer 242 may be different (e.g., less) than the temperature associated with the ALD process 300 for forming the first P-type work function layer 240. As a result, the first P-type work function layer 240 and the second P-type work function layer 242 may have different oxygen concentrations. For example, in an embodiment, oxygen concentration in the second P-type work function layer 242 is higher than oxygen concentration in the first P-type work function layer 240.

The above embodiments include various combinations of different compositions of the first P-type work function layer 240 and the second P-type work function layer 242. For example, in an embodiment represented by FIG. 14A, the first P-type work function layer 240 includes oxygen-containing titanium nitride formed at a temperature in a range between about 300° C. and about 400° and a second P-type work function layer 242 includes titanium tungsten nitride (TiWN) or tungsten-containing titanium nitride. In another embodiment represented by FIG. 14B, the first P-type work function layer 240 includes oxygen-containing titanium nitride formed at a first temperature in a range between about 300° C. and about 400° and a second P-type work function layer 242 includes oxygen-containing titanium nitride formed at a second temperature in a range between about 300° C. and about 400°, the first temperature may be different from (e.g., lower than, greater than) or equal to the second temperature, and oxygen concentration in the second P-type work function layer 242 may be higher than, equal to, or lower than the oxygen concentration in the first P-type work function layer 240.

In the above embodiments described with reference to FIGS. 14-16, the second P-type work function layer 242 is a single-layer work function layer 242. In some alternative embodiments, the second P-type work function layer 242 may be a multi-layer work function layer. With reference to FIG. 17, the second P-type work function layer 242 includes a first layer 242a and a second layer 242b over the first layer 242a. The first layer 242a and the second layer 242b are P-type work function layers having different compositions. In an embodiment, the first P-type work function layer 240 includes oxygen-containing titanium nitride formed at the first temperature in a range between about 300° C. and about 400°, the first layer 242a includes tungsten nitride (WN), and the second layer 242b includes titanium tungsten nitride (TiWN). It is noted that, to provide great adhesion between the second P-type work function layer 242 and the photoresist layer formed in subsequent process to achieve satisfactory patterning, the TiWN-based second layer 242b is formed over the WN-based first layer 242a. A thickness T3 of the first layer 242a may be equal to or different than (e.g., greater than or less than) a thickness T4 of the second layer 242b, and a total thickness (i.e., T3+T4) of the first layer 242a and the second layer 242b is equal to the thickness T2. In an embodiment, a ratio of the thickness T3 to the thickness T2 is equal to 0.5. In another embodiment, a ratio of the thickness T3 to the thickness T2 is equal to 2. In some embodiments, depending on the selection of tungsten-containing precursors, the first layer 242a may include carbon-containing tungsten nitride (WN) (“WN:C” or “WCN”), and the second layer 242b may include carbon-containing titanium tungsten nitride (TiWN).

In the above embodiments, examples of the first mechanism are described. An example of the second mechanism includes introducing the second type dopants (e.g., silicon, aluminum, tantalum) to the P-type work function structure 241 to reduce the work function position for the P-type work function structure 241. For example, with respect to FIG. 14C, according to the second mechanism, to reduce the work function position for the P-type work function structure 241, the first P-type work function layer 240 may include silicon-containing titanium nitride (e.g., TiSiN). The second type dopants (e.g., silicon) may be introduced in a way similar to the first type dopants (e.g., tungsten) described with reference to FIG. 16. For example, to form silicon doped TiN-based first P-type work function layer 240 (e.g., TiSiN), an ALD process similar to the ALD process 350 that includes the first half cycle 350A and the second half cycle 350B may be performed. One of the differences between these two ALD processes may include, instead of using a tungsten-containing metal precursor to introduce the first type dopants, a second-type-dopant-containing precursor (e.g., silicon-containing precursor) is implemented to introduce the second type dopants (e.g., silicon) to dope the TiN-based first P-type work function layer 240. A concentration of silicon in the silicon doped TiN-based first P-type work function layer 240 is less than about 20%. If the concentration of silicon is greater than 20%, the gate resistance Rg of the resulted gate stack may be too high, disadvantageously affecting the performance of the transistor. The concentration of silicon in the first P-type work function layer 240 may be uniform or non-uniform, in a way similar to the tungsten concentration described above with reference to FIG. 16. In embodiments according to the second mechanism, the second P-type work function layer 242 formed over the silicon doped TiN-based first P-type work function layer 240 may include titanium nitride formed at a third temperature higher than 400° C. and has an oxygen concentration less than that of the titanium-and-nitrogen-containing P-type work function layer (e.g., the first P-type work function layer 240 formed according to the first mechanism) formed at the first temperature in the range between about 300° C. and 400° C. In some other implementations, as represented by FIG. 14D, the second type dopants (e.g., silicon, aluminum, tantalum) may be introduced to the second P-type work function 242 of the P-type work function structure 241. For example, the first P-type work function layer 240 may include titanium nitride formed at the third temperature higher than 400° C. and has an oxygen concentration less than that of the titanium-and-nitrogen-containing P-type work function layer (e.g., the P-type work function layer 240 formed according to the first mechanism) formed at the first temperature in the range between about 300° C. and 400° C.; the second P-type work function 242 may include silicon-containing titanium nitride (e.g., TiSiN) and may be formed by the ALD process described with reference to FIG. 14C.

In some embodiments, the structure 200 includes a first P-type transistor having a threshold V_{T0} and including a first P-type work function layer comprising titanium nitride formed at the third temperature higher than 400° C. and a second P-type work function layer over the first P-type work function layer comprising titanium nitride formed at the third temperature higher than 400° C. The structure 200 also includes a second P-type transistor having a threshold V_{T1} and including the P-type work function structure 241 (e.g., an oxygen-containing TiN-based first P-type work function layer 240 and a TiWN-based second P-type work function layer 242) formed according to the first mechanism described above with refence to FIG. 14. The structure 200 also includes a third P-type transistor having a threshold V_{T2} and including a P-type work function structure (e.g., a TiSiN-based first P-type work function layer 240 and a TiN-based second P-type work function layer 242) formed according to the second mechanism. The configurations of the gate stacks of the three P-type transistors are substantially the same except for the different configurations of the P-type work function structure. Compared to the first P-type transistor, by introducing dopants to the P-type work function structure, different threshold voltages may be achieved without changing the thickness of the P-type work function structure. In an embodiment, the threshold V_{T1} is less than the threshold V_{T0}, and the threshold V_{T2} is greater than the threshold V_{T0}. Therefore, the threshold voltage tuning range of the P-type transistor may be advantageously widened to meet various design requirements.

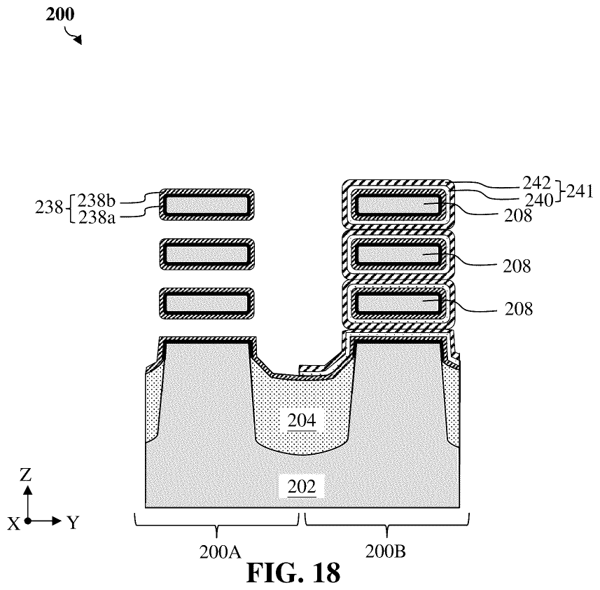

Referring to FIGS. 1 and 18, method 100 includes a block 122 where the P-type work function structure 241 is patterned, thereby removing the portion of the P-type work function structure 241 in the first device region 200A. After forming the P-type work function structure 241, the P-type work function structure 241 is patterned. Operations at block 122 may apply a lithography process that includes forming a resist (or photoresist) layer over the P-type work function structure 241 by spin coating, performing a pre-exposure baking process, performing an exposure process, performing a post-exposure baking process, and developing the exposed resist layer in a developer solution. After the development, the resist layer becomes a resist pattern. While using the resist pattern as an etch mask, an etching process is performed to remove the portion of the P-type work function structure 241 formed in the first device region 200A.

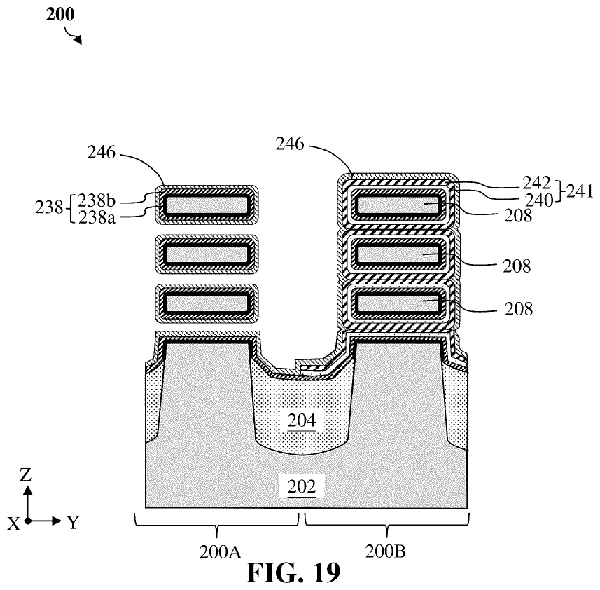

Referring to FIGS. 1 and 19, method 100 includes a block 124 where an N-type work function layer 246 is formed over the structure 200. After the patterning of the P-type work function structure 241, an N-type work function layer 246 is deposited over the gate dielectric layer 238 using suitable processes, such as atomic layer deposition (ALD). In an embodiment, the N-type work function layer 246 is conformally deposited over the structure 200 to have a generally uniform thickness over the top surface of the structure 200 to partially fill the gate trenches 234 in the first device region 200A and the gate openings 236 in the first device region 200A. In some embodiments, the N-type work function layer 246 may include a metal with sufficiently low effective work function such as Ti, Al, TaC, TaCN, TaSiN, or combinations thereof. For example, the N-type work function layer 246 may include an aluminum-containing N-type work function layer formed of titanium aluminum (TiAl), titanium aluminum carbide (TiAlC), tantalum aluminum (TaAl), or titanium aluminum nitride (TiAlN), or other suitable materials. In some other embodiments, the aluminum-containing N-type work function layer 246 (e.g., TiAlC) may be formed by an ALD process similar to the ALD process 350 by selecting suitable precursors (titanium-containing precursor, carbon-containing precursor, aluminum-containing precursor), and the aluminum concentration of the aluminum-containing N-type work function layer 246 may be adjusted by adjusting its corresponding ratio of the number B to the number A, thereby adjusting the work function of the aluminum-containing N-type work function layer 246 to obtain a wider threshold voltage tuning range for N-type transistors.

Referring to FIGS. 1, 20 and 21A-21B, method 100 includes a block 126 where one or more conductive layers are formed over the substrate 202 to finish the fabrication of functional gate stacks 255 and 260. FIG. 21A depicts an enlarged portion of the gate stack 255 formed in the gate trench 234 in the first device region 200A, and FIG. 21B depicts an enlarged portion of the gate stack 260 formed in the gate trench 234 in the second device region 200B. In some embodiments of the present disclosure, the one or more conductive layers includes a first protective layer 248 and a second protective layer 250 conformally formed over the N-type work function layer 246 and a metal electrode layer 252 formed over the second protective layer 250. In an embodiment, the first protective layer 248 includes titanium nitride, and a deposition thickness of the first protective layer 248 may be less than the thickness T1 of the first P-type work function layer 240. In an embodiment, both the first protective layer 248 and the first P-type work function layer 240 includes oxygen-containing titanium nitride, and an oxygen concentration of the first protective layer 248 is higher than an oxygen concentration of the first P-type work function layer 240. The second protective layer 250 may include silicon. The metal electrode layer 252 may include a conductive material, such as Al, W, and/or Cu and may be deposited using ALD, CVD, PVD, plating, or other suitable processes to fill any remaining portion of gate trenches 234. In various embodiments, a planarization process (e.g., chemical mechanical polishing (CMP) process) may be performed to remove excessive portions of the materials over the ILD layer 232, thereby finalizing the structure of gate stack 255 in the first device region 200A and the gate stack 260 in the second device region 200B. In this illustrated embodiment, the gate stack 255 formed in the gate trench 234 in the first device region 200A includes the metal electrode layer 252, and the gate stack 260 formed in the gate trench 234 in the second device region 200B does not include the metal electrode layer 252.

In the above embodiments, the N-type work function layer 246 is formed in both the first device region 200A and the second device region 200B. In some alternative embodiments, as represented by FIG. 22, the portion of the N-type work function layer 246 formed in the second device region 200B is removed. In another alternative embodiment, portions of the first protective layer 248 and the second protective layer 250 formed in the second device region 200B may also be removed. The second mechanism (e.g., introducing second type dopants to reduce work function) described above may be applied to adjust the threshold voltage of the P-type transistors formed in the second device region 200B represented by FIG. 22.

After forming the gate stacks 255 and 260, further process are performed. Such further processes may include forming a silicide layer (not depicted) over the source/drain features and a multi-layer interconnect (MLI) structure (not depicted) over the structure 200. The MLI may include various interconnect features, such as vias and conductive lines, source/drain contacts, gate contacts, disposed in dielectric layers, such as etch-stop layers and ILD layers (such as ILD layer 232). In some embodiments, the vias are vertical interconnect features configured to interconnect device-level contacts, such as source/drain contacts formed over the source/drain features and gate contacts (not depicted) formed over the gate stacks 255 and 260.

Although not intended to be limiting, one or more embodiments of the present disclosure provide many benefits to semiconductor devices and the formation thereof. In some embodiments, the present disclosure provides methods for extending threshold voltage tuning range of P-type transistors without adjusting a total thickness of the P-type work function layer(s).

The present disclosure provides for many different embodiments. Semiconductor structures and methods of fabrication thereof are disclosed herein. In one exemplary aspect, the present disclosure is directed to a method. The method includes forming a dielectric layer over a portion of a substrate, forming a first p-type work function layer over the dielectric layer, wherein the first p-type work function layer comprises titanium nitride, forming a second p-type work function layer over the first p-type work function layer, wherein the second p-type work function layer comprises titanium nitride with dopants, forming an aluminum-containing N-type work function layer over second p-type work function layer, wherein the dopants in the second p-type work function layer reduces aluminum diffusion from aluminum-containing N-type work function layer into the second p-type work function layer, and forming a metal layer over the aluminum-containing N-type work function layer.

In some embodiments, an atomic percentage of titanium in the second p-type work function layer is less than an atomic percentage of titanium in the first p-type work function layer. In some embodiments, a work function of the second p-type work function layer is less than a work function of the first p-type work function layer. In some embodiments, the dopants in the second p-type work function layer may include oxygen, tungsten, or fluorine. In some embodiments, the dopants in the second p-type work function layer may include tungsten, and the forming of the second p-type work function layer may include performing an atomic layer deposition (ALD) process, and a cycle of the atomic layer deposition (ALD) process includes performing a number of first loops to form first monolayers of titanium nitride, and after the performing of the number of first loops, performing a number of second loops to form second monolayers of tungsten nitride over the first monolayers. In some embodiments, the method may also include adjusting a ratio of the number of the second loops to the number of the first loops to adjust a concentration of tungsten in the second p-type work function layer. In some embodiments, precursors for forming the first monolayers of titanium nitride may include ammonia and a titanium-containing precursor, and precursors for forming the second monolayers of tungsten nitride comprise ammonia and a tungsten-containing precursor. In some embodiments, the method may also include adjusting a ratio of a pulse duration of ammonia to a pulse duration of the tungsten-containing precursor to adjust a concentration of tungsten in the second p-type work function layer. In some embodiments, the method may also include, before the forming of the second p-type work function layer, forming a third p-type work function layer over the first p-type work function layer, wherein the first p-type work function layer may include titanium nitride, the second p-type work function layer may include tungsten-containing titanium nitride, and the third p-type work function layer may include tungsten nitride. In some embodiments, the first p-type work function layer may include oxygen-containing titanium nitride.

In another exemplary aspect, the present disclosure is directed to a method. The method includes receiving a structure comprising a plurality of nanostructures over a substrate and a source/drain feature coupled to the plurality of nanostructures, forming a gate dielectric layer over and wrapping around the nanostructures, and performing an atomic layer deposition process to forming a p-type work function layer over the gate dielectric layer, wherein a cycle of the atomic layer deposition process may include a first half cycle followed by a second half cycle, and the first half cycle may include sequentially pulsing a first metal precursor and a first non-metal precursor in a chamber, and the second half cycle may include sequentially pulsing a second metal precursor and a second non-metal precursor in the chamber, wherein the first metal precursor and the second metal precursor contain different metal elements.

In some embodiments, the p-type work function layer may include TiWN, the first metal precursor contains titanium, and the second metal precursor contains tungsten. In some embodiments, the first non-metal precursor and the second non-metal precursor have a same composition. In some embodiments, the second half cycle of the atomic layer deposition process may include repeating the sequentially pulsing of the second metal precursor and the second non-metal precursor multiple times. In some embodiments, the method may also include, before the performing of the atomic layer deposition process, depositing another work function layer on the gate dielectric layer, wherein the another work function layer and the second metal precursor contain a same metal element. In some embodiments, the method may also include, after the performing of the atomic layer deposition process, depositing an n-type work function layer over the p-type work function layer, and forming a metal layer over the n-type work function layer.

In yet another exemplary aspect, the present disclosure is directed to a semiconductor device. The semiconductor device includes a substrate, a gate dielectric layer over a portion of the substrate, a first titanium-and-nitrogen containing work function layer over the gate dielectric layer, a second titanium-and-nitrogen containing work function layer on the first titanium-and-nitrogen containing work function layer, wherein composition of the second titanium-and-nitrogen containing work function layer is different from composition of the first titanium-and-nitrogen containing work function layer, an aluminum-containing work function layer disposed over the second titanium-and-nitrogen containing work function layer, wherein the second titanium-and-nitrogen containing work function layer contains element configured to reduce aluminum diffusion from aluminum-containing work function layer into the second titanium-and-nitrogen containing work function layer, and a conductive layer disposed over the aluminum-containing work function layer.

In some embodiments, the semiconductor device may also include a plurality of nanostructures over the substrate, wherein the gate dielectric layer, the first titanium-and-nitrogen containing work function layer, and the second titanium-and-nitrogen containing work function layer are disposed over and wrap around the plurality of nanostructures. In some embodiments, the second titanium-and-nitrogen containing work function layer contains oxygen, tungsten, or fluorine. In some embodiments, the second titanium-and-nitrogen containing work function layer may include TiWN.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit-line conductor and word line conductor, one can achieve different resistances for the conductors. However, other techniques to vary the resistances of the metal conductors may also be utilized as well.

What is claimed is:

1. A method, comprising:
forming a dielectric layer over a portion of a substrate;
forming a first p-type work function layer over the dielectric layer, wherein the first p-type work function layer comprises titanium nitride;
forming a second p-type work function layer over the first p-type work function layer, wherein the second p-type work function layer comprises titanium nitride with dopants;
forming an aluminum-containing N-type work function layer over second p-type work function layer, wherein the dopants in the second p-type work function layer reduces aluminum diffusion from aluminum-containing N-type work function layer into the second p-type work function layer; and
forming a metal layer over the aluminum-containing N-type work function layer.

2. The method of claim 1, wherein an atomic percentage of titanium in the second p-type work function layer is less than an atomic percentage of titanium in the first p-type work function layer.

3. The method of claim 1, wherein a work function of the second p-type work function layer is less than a work function of the first p-type work function layer.

4. The method of claim 1, wherein the dopants in the second p-type work function layer comprises oxygen, tungsten, or fluorine.

5. The method of claim 4, wherein the dopants in the second p-type work function layer comprises tungsten, and the forming of the second p-type work function layer comprises performing an atomic layer deposition (ALD) process, and a cycle of the atomic layer deposition (ALD) process comprising:
performing a number of first loops to form first monolayers of titanium nitride; and
after the performing of the number of first loops, performing a number of second loops to form second monolayers of tungsten nitride over the first monolayers.

6. The method of claim 5, further comprising: adjusting a ratio of the number of the second loops to the number of the first loops to adjust a concentration of tungsten in the second p-type work function layer.

7. The method of claim 5, wherein precursors for forming the first monolayers of titanium nitride comprise ammonia and a titanium-containing precursor, and precursors for forming the second monolayers of tungsten nitride comprise ammonia and a tungsten-containing precursor.

8. The method of claim 7, further comprising: adjusting a ratio of a pulse duration of ammonia to a pulse duration of the tungsten-containing precursor to adjust a concentration of tungsten in the second p-type work function layer.

9. The method of claim 1, further comprising:
before the forming of the second p-type work function layer, forming a third p-type work function layer over the first p-type work function layer,
wherein the first p-type work function layer comprises titanium nitride, the second p-type work function layer comprises tungsten-containing titanium nitride, and the third p-type work function layer comprises tungsten nitride.

10. The method of claim 1, wherein the first p-type work function layer comprises oxygen-containing titanium nitride.

11. A method, comprising:
receiving a structure comprising:
a plurality of nanostructures over a substrate, and
a source/drain feature coupled to the plurality of nanostructures;
forming a gate dielectric layer over and wrapping around the nanostructures; and
performing an atomic layer deposition process to forming a p-type work function layer over the gate dielectric layer, wherein a cycle of the atomic layer deposition process comprises a first half cycle followed by a second half cycle, and the first half cycle comprises sequentially pulsing a first metal precursor and a first non-metal precursor in a chamber, and the second half cycle comprises sequentially pulsing a second metal precursor and a second non-metal precursor in the chamber, wherein the first metal precursor and the second metal precursor contain different metal elements.

12. The method of claim 11, wherein the p-type work function layer comprises TiWN, the first metal precursor contains titanium, and the second metal precursor contains tungsten.

13. The method of claim 11, wherein the first non-metal precursor and the second non-metal precursor have a same composition.

14. The method of claim 11, wherein the second half cycle of the atomic layer deposition process comprises repeating the sequentially pulsing of the second metal precursor and the second non-metal precursor multiple times.

15. The method of claim 11, further comprising:
before the performing of the atomic layer deposition process, depositing another work function layer on the gate dielectric layer, wherein the another work function layer and the second metal precursor contain a same metal element.

16. The method of claim 11, further comprising:
after the performing of the atomic layer deposition process, depositing an n-type work function layer over the p-type work function layer; and
forming a metal layer over the n-type work function layer.

17. A semiconductor device, comprising:
a substrate;
a gate dielectric layer over a portion of the substrate;
a first titanium-and-nitrogen containing work function layer over the gate dielectric layer;
a second titanium-and-nitrogen containing work function layer on the first titanium-and-nitrogen containing work function layer, wherein composition of the second titanium-and-nitrogen containing work function layer is different from composition of the first titanium-and-nitrogen containing work function layer;
an aluminum-containing work function layer disposed over the second titanium-and-nitrogen containing work function layer, wherein the second titanium-and-nitrogen containing work function layer contains element configured to reduce aluminum diffusion from aluminum-containing work function layer into the second titanium-and-nitrogen containing work function layer; and
a conductive layer disposed over the aluminum-containing work function layer.

18. The semiconductor device of claim 17, further comprising:
a plurality of nanostructures over the substrate,
wherein the gate dielectric layer, the first titanium-and-nitrogen containing work function layer, and the second titanium-and-nitrogen containing work function layer are disposed over and wrap around the plurality of nanostructures.

19. The semiconductor device of claim 17, wherein the second titanium-and-nitrogen containing work function layer contains oxygen, tungsten, or fluorine.

20. The semiconductor device of claim 19, wherein the second titanium-and-nitrogen containing work function layer comprises TiWN.
